(19) United States
(12) Patent Application Publication
(10) Pub. No.: US 2026/0334307 A1
(43) Pub. Date: Oct. 22, 2026

(54) MEMORY DEVICE

(71) Applicant: NANYA TECHNOLOGY CORPORATION, New Taipei City (TW)

(72) Inventors: William Wu Shen, New Taipei City (TW); Pin-hsiu Hsieh, New Taipei City (TW)

(73) Assignee: NANYA TECHNOLOGY CORPORATION, New Taipei City (TW)

(21) Appl. No.: 19/185,138

(22) Filed: Apr. 21, 2025

(51) Int. Cl. H10W 90/00; H10B 80/00; H10W 20/20; H10W 20/49; H10W 42/60

(52) U.S. Cl. CPC H10W 90/00; H10B 80/00; H10W 20/20; H10W 20/49; H10W 42/60

(57) ABSTRACT

A memory device including a second region and a first region is provided. The memory device includes a bottom logic die including a first global repair circuit in the second region and a first device layer in the first region, a memory die stack on the bottom logic die and including at least two memory dies stacked on each other, a top die on the memory die stack and including a second global repair circuit in the second region and a third device layer in the first region, and a redistribution layer on the top die. Each memory die includes a first local repair circuit in the second region and a second device layer in the first region. The top die includes top repair vias configured in the second region and connecting to the second global repair circuit. The redistribution layer is electrically connected to the top repair vias.

### BACKGROUND

### Technical Field

The present invention relates to a semiconductor device, and more particularly to a memory device.

### Description of Related Art

The test interface of a 3D stack such as a high bandwidth memory (HBM) is commonly designed in the base logic die. This physical architecture limits the test feasibility especially while a 3D stack (i.e., HBM) is sitting on an interposer during or after 2.5D packaging processes.

The base logic die of the 3D stack (e.g., HBM) may be served as an interface or an organizer with a computing chip, and thus the pads and/or the bumps included in the base logic die are impossible to be accessed directly by micro/nano scale probe tips after the 3D stack (e.g., HBM) is mounting on the interposer. However, the problem may not just occur on a memory stack but also on various heterogeneous chiplets integrations by advanced packaging technologies, so it may be restrictive as probing can only be conducted before the system assembly.

This Discussion of the Background section is provided for background information only. The statements in this Discussion of the Background are not an admission that the subject matter disclosed in this Discussion of the Background section constitutes prior art to the present disclosure, and no part of this Discussion of the Background section may be used as an admission that any part of this application, including this Discussion of the Background section, constitutes prior art to the present disclosure.

### SUMMARY

The disclosure provides a memory device in which a bottom logic die including a first global repair circuit in a second region and a top die including a second global repair circuit in the second region are respectively at a bottom side and a top side of a memory die stack, and a redistribution layer is disposed on the top die and electrically connected to the second global repair circuit. As such, the test and repair procedures can be executed from the bottom logic die and/or from the top die, and the probing can still be conducted through the redistribution layer after the system assembly, and thus the quality and the yield of the memory device can be improved.

An embodiment of the present disclosure provides a memory device including a first region and a second region, wherein the memory device includes a bottom logic die, a memory die stack, a top die, and a redistribution layer. The bottom logic die includes a first global repair circuit configured in the second region and a first device layer configured in the first region. The memory die stack is on the bottom logic die and including at least two memory dies stacked on each other, wherein each memory die includes a first local repair circuit configured in the second region and a second device layer configured in the first region. The top die is on the memory die stack and including a second global repair circuit configured in the second region and a third device layer configured in the first region, wherein the top die includes a plurality of top repair vias configured in the second region and connecting to the second global repair circuit. The redistribution layer is on the top die and electrically connected to the plurality of top repair vias.

In some embodiments, the memory device further includes a plurality of test pads on the redistribution layer and electrically connected to the plurality of top repair vias through the redistribution layer.

In some embodiments, the redistribution layer includes a plurality of connection pads respectively connecting to the plurality of top repair vias and a plurality of wirings respectively connecting the plurality of test pads to the plurality of connection pads, and sizes of the plurality of connection pads are smaller than sizes of the plurality of test pads.

In some embodiments, the bottom logic die includes a plurality of bottom repair vias configured in the second region and connecting to the first global repair circuit, a diameter of one of the plurality of bottom repair vias is smaller than a diameter of one of the plurality of top repair vias.

In some embodiments, the diameter of one of the plurality of top repair vias is greater than a diameter of a via connecting to the second device layer in each memory die.

In some embodiments, the diameter of the one of the plurality of top repair vias is greater than a diameter of a via connecting to the first local repair circuit in each memory die.

In some embodiments, the diameter of the one of the plurality of top repair vias is greater than 20 μm.

In some embodiments, the bottom logic die includes a plurality of bottom repair vias configured in the second region and connecting to the first global repair circuit, and a height of one of the plurality of bottom repair vias in a direction where the memory dies are stacked on each other is smaller than a height of one of the plurality of top repair vias.

In some embodiments, the height of the one of the plurality of top repair vias is greater than a height of a via connecting to the second device layer in each memory die in the direction.

In some embodiments, the height of the one of the plurality of top repair vias is greater than a height of a via connecting to the first local repair circuit in each memory die in the direction.

In some embodiments, the height of the one of the plurality of top repair vias is greater than 175 μm.

In some embodiments, the second global repair circuit is configured to receive a control signal from at least one of the plurality of test pads.

In some embodiments, the second global repair circuit includes a bidirectional buffer circuit.

In some embodiments, the second global repair circuit includes an electrostatic discharge (ESD) protection circuit connecting to the bidirectional buffer circuit.

Based on the above, in the aforementioned memory device, the bottom logic die including the first global repair circuit in the second region and the top die including the second global repair circuit in the second region are respectively at the bottom side and the top side of the memory die stack, and the redistribution layer is disposed on the top die and electrically connected to the second global repair circuit. As such, the test and repair procedures can be activated from the bottom logic die and/or from the top die, and the probing can still be conducted through the redistribution layer after the system assembly, and thus the quality and the yield of the memory device can be improved.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic cross-sectional view of a memory device according to an embodiment of the disclosure.

FIG. 2 is a schematic view of a second global repair circuit according to an embodiment of the disclosure.

### DESCRIPTION OF THE EMBODIMENTS

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

The invention will be described more comprehensively below with reference to the drawings for the embodiments. However, the invention may also be implemented in different forms rather than being limited by the embodiments described in the invention. Thicknesses of layer and region in the drawings are enlarged for clarity. The same reference numbers are used in the drawings and the description to indicate the same or like parts, which are not repeated in the following embodiments.

It will be understood that when an element is referred to as being "on" or "connected" to another element, it may be directly on or connected to the other element or intervening elements may be present. If an element is referred to as being "directly on" or "directly connected" to another element, there are no intervening elements present. As used herein, "connection" may refer to both physical and/or electrical connections, and "electrical connection" or "coupling" may refer to the presence of other elements between two elements. As used herein, " electrical connection" may refer to the concept including a physical connection (e.g., wired connection) and a physical disconnection (e.g., wireless connection).

As used herein, "about", "approximately" or "substantially" includes the values as mentioned and the average values within the range of acceptable deviations that can be determined by those of ordinary skill in the art. Consider to the specific amount of errors related to the measurements (i.e., the limitations of the measurement system), the meaning of "about" may be, for example, referred to a value within one or more standard deviations of the value, or within ±30%, ±20%, ±10%, ±5%. Furthermore, the "about", "approximate" or "substantially" used herein may be based on the optical property, etching property or other properties to select a more acceptable deviation range or standard deviation, but may not apply one standard deviation to all properties.

The terms used herein are used to merely describe exemplary embodiments and are not used to limit the present disclosure. In this case, unless indicated in the context specifically, otherwise the singular forms include the plural forms.

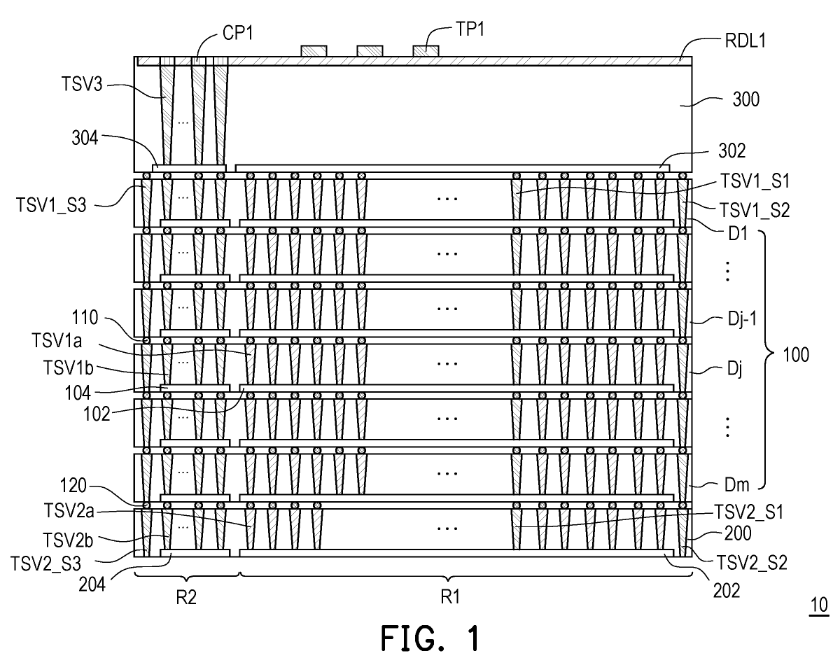

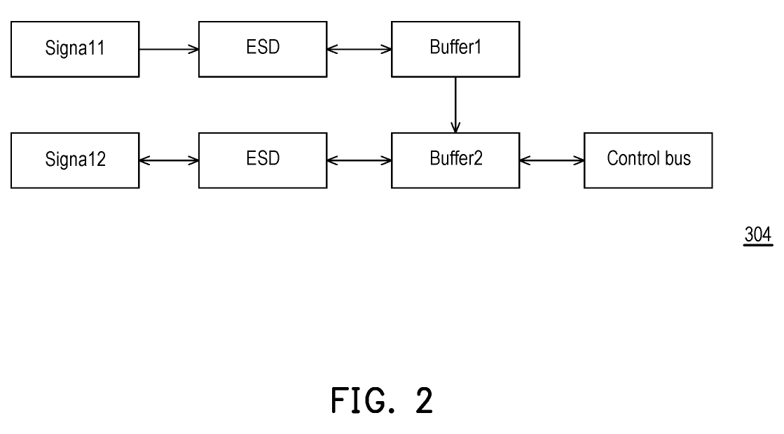

FIG. 1 is a schematic cross-sectional view of a memory device according to an embodiment of the disclosure. FIG. 2 is a schematic view of a second global repair circuit according to an embodiment of the disclosure.

Referring to FIG. 1, a memory device 10 includes a first region R1 and a second region R2, and wherein the memory device 10 includes a memory die stack 100, a bottom logic die 200, a top die 300, and a redistribution layer RDL1. In some embodiments, the first region R1 may be, for example, a cell region where memory cells are disposed, and the second region R2 may be, for example, a repair region where repair circuits are disposed. In this embodiment, the memory cells and the repair circuits of the memory dies D1 to Dm are stacked and overlapped with each other in a vertical direction, so the first region R1 may include the same scope in the vertical direction, and the second region R2 may include the same range in the vertical direction, but the disclosure is not limited thereto. In some other embodiments, when the memory dies are stacked with each other by a horizontal offset in the vertical direction, the first region R1 and the second region R2 may include different ranges in the vertical direction. In some embodiments, the second region R2 may be, for example, adjacent to the first region R1.

The memory die stack 100 is disposed on the bottom logic die 200 and includes at least two memory dies D1 to Dm stacked on each other, wherein each of the memory dies D1 to Dm includes a device layer configured in the first region and a first local repair circuit configured in the second region R2. For example, the memory die Dj among the memory dies D1 to Dm includes a device layer 102 configured in the first region R1 and a first local repair circuit 104 configured in the second region R2. The bottom logic die 200 includes a device layer 202 configured in the first region R1 and a first global repair circuit 204 configured in the second region R2.

In some embodiments, the device layer 102 may include memory devices in a device region and wirings in a connection region. The device region may be a region of the memory die Dj where the memory array is disposed. The connection region may be a region of the memory die Dj where connection members such as through-silicon vias (TSVs), pads, or wiring layers/patterns are disposed. For example, the device layer 102 shown in FIG. 1 may be a wiring layer connected to conductive members TSV1a of the memory die Dj in the first region R1, but the disclosure is not limited thereto. In some embodiments, the conductive members TSV1a may be through-silicon vias for transmitting signals. In some embodiments, the conductive members TSV1a may include any suitable conductive materials such as metals or metal alloys including one or more of Al, AlCu, Cu, Ti, TiN, W, and the like.

In some embodiments, the device layer 202 may include logic devices in a device region and wirings in a connection region. The device region may be a region of the bottom logic die 200 where the logic devices are disposed. The connection region may be a region of the bottom logic die 200 where connection members such as through-silicon vias (TSVs), pads, or wiring layers/patterns are disposed. For example, the device layer 202 shown in FIG. 1 may be a wiring layer connected to conductive members TSV2a of the memory die Dj in the first region R1, but the disclosure is not limited thereto. In some embodiments, the conductive members TSV2a may be through-silicon vias (TSVs) for transmitting signals. In some embodiments, the conductive members TSV2a may include any suitable conductive materials such as metals or metal alloys including one or more of Al, AlCu, Cu, Ti, TiN, W, and the like.

In some embodiments, during the test procedure, the first global repair circuit 204 in the bottom logic die 200 will kick off a series command to the first local repair circuits 104 to activate the monitor and test sequences. A global tester in the first global repair circuit 204 may transmit a test pattern through a signal path (e.g., a path including the wirings and the conductive members TSV1a in the memory die Dj), and the first local repair circuit 104 will monitor the pattern and will also transmit a test pattern on a bidirectional net for the first global repair circuit 204 to verify. If any signal path fails to response, it means that the wirings constituted the signal path has problem, and then the global repair circuit will initial a path repair action. In some embodiments, the path repair action may include following steps for instance. In the case where a TSV is identified as failure (i.e., a broken TSV) in the memory die Dj, a pass command from the first global repair circuit 204 is transmitted to the first local repair circuit 104 in the memory die Dj and the first local repair circuit 104 in the memory die (e.g., the memory die Dj-1) adjacent to the memory die Dj to initiate a re-route repair action. That is, the re-route repair action is completed by the effort on both the memory die Dj and the memory die Dj-1. For example, the first local repair circuit 104 in the memory die Dj will take action to cut a wire in the wiring layer connected to the broken TSV and to route the signal to a spare TSV (e.g., a spare conductive member TSV_S1 in the memory die Dj), and the first local repair circuit 104 in the memory die Dj-1 will also take action to cut a wire in the wiring layer connected to the broken TSV in the memory die Dj and to route the signal to the spare TSV of the memory die Dj.

In some embodiments, each of the memory dies D1 to Dm may include conductive members TSV1b configured in the second region R2 and electrically connected to the first local repair circuit 104, and the bottom logic die 200 may include conductive members TSV2b configured in the second region R2 and electrically connected to the first global repair circuit 204. The conductive members TSV1b and TSV2b may each be a through-silicon via (TSV), and may include any suitable conductive materials such as metals or metal alloys including one or more of Al, AlCu, Cu, Ti, TiN, W, and the like.

In some embodiments, each of the memory dies D1 to Dm may include spare conductive members TSV1_S1 and TSV1_S2 configured in the first region R1, and spare conductive members TSV1_S3 configured in the second region R2. In some embodiments, each spare conductive member TSV1_S1, TSV1_S2, and TSV1_S3 may be a through-silicon via (TSV), and may include any suitable conductive materials such as metals or metal alloys including one or more of Al, AlCu, Cu, Ti, TiN, W, and the like. In some embodiments, the bottom logic die 200 may include spare conductive members TSV2_S1 and TSV2_S2 configured in the first region R1, and TSV2_S3 configured in the second region R2. In some embodiments, each spare conductive member TSV2_S1, TSV2_S2, and TSV2_S3 may be a through-silicon via (TSV), and may include any suitable conductive materials such as metals or metal alloys including one or more of Al, AlCu, Cu, Ti, TiN, W, and the like.

In some embodiments, each of the memory dies D1 to Dm may include conductive members 110 electrically connected the memory dies D1 to Dm to each other. For example, the conductive members 110 of the memory die Dj may be respectively disposed on the conductive members TSV1a and TSV1b and the spare conductive members TSV1_S1, TSV1_S2, and TSV1_S3, and may be electrically connected the conductive members TSV1a and TSV1b and the spare conductive members TSV1_S1, TSV1_S2, and TSV1_S3 in the memory die Dj to the conductive members TSV1a and TSV1b and the spare conductive members TSV1_S1, TSV1_S2, and TSV1_S3 in the memory die Dj-1, respectively. In some embodiments, each conductive members 110 may be a micro-bump, and may include any suitable conductive materials such as metals or metal alloys including one or more of Al, AlCu, Cu, Ti, TiN, W, and the like.

In some embodiments, the bottom logic die 200 may include conductive members 120 electrically connected the bottom logic die 200 to the memory die Dm. For example, the conductive members 120 of the bottom logic die 200 may be respectively disposed on the conductive members TSV2a and TSV2b and the spare conductive members TSV2_S1, TSV2_S2, and TSV2_S3, and may be electrically connected the conductive members TSV2a and TSV2b and the spare conductive members TSV2_S1, TSV2_S2, and TSV2_S3 in the bottom logic die 200 to the conductive members TSV1a and TSV1band the spare conductive members TSV1_S1, TSV1_S2, and TSV1_S3 in the memory die Dm, respectively. In some embodiments, each conductive members 120 may be a micro-bump, and may include any suitable conductive materials such as metals or metal alloys including one or more of Al, AlCu, Cu, Ti, TiN, W, and the like.

The top die 300 is disposed on the memory die stack 100 and including a device layer 302 disposed in the first region R1 and a second global repair circuit 304 configured in the second region R2. The top die 300 is electrically connected to the memory die D1 among the memory die stack 100 through the connection members 110 disposed therebetween. For example, the conductive members 110 of the memory die D1 electrically connect the device layer 302 of the top die 300 to the conductive members TSV1a of the memory die D1 in the first region R1, and electrically connect the second global repair circuit 304 of the top die 300 to the conductive members TSV1b of the memory die D1 in the second region R2. In some embodiments, the device layer 302 may include memory devices in a device region and wirings in a connection region. The device region may be a region of the top die 300 where the memory array is disposed. The connection region may be a region of the top die 300 where connection members such as connection pads, or wiring layers/patterns are disposed. For example, the device layer 302 shown in FIG. 1 may be a wiring layer connected to the conductive members 110 of the memory die D1 in the first region R1, but the disclosure is not limited thereto.

In this embodiment, the top die 300 includes top repair vias TSV3 configured in the second region R2 and connecting to the second global repair circuit 304, as such the test and repair procedures can be activated from the bottom logic die 200 and/or from the top die 300, and the probing can still be conducted through a redistribution layer (e.g., the redistribution layer RDL1 on the top die 300) after the system assembly, and thus the quality and the yield of the memory device 10 can be improved. For example, during the test procedure, if the series command from the bottom logic die 200 cannot access the memory die Dj-1, it is assumed that one of the wirings (e.g., control path) for the first local repair circuit 104 in the memory die Dj-1 is broken. In this case, the second global repair circuit 304 in the top die 300 can kick off the series command through the top repair via TSV3, so that the first local repair circuit 104 in the memory die Dj-1 can be activated from the top die 300, and the first local repair circuit 104 in the memory die Dj can be activated from the bottom logic die 200, so that the re-route repair action can be completed by conducting a cutting action and a re-route action on both the memory die Dj and the memory die Dj-1.

In some embodiments, the top repair vias TSV3 may each be a through-silicon via (TSV), and may include any suitable conductive materials such as metals or metal alloys including one or more of Al, AlCu, Cu, Ti, TiN, W, and the like. In some embodiments, a height of one of the top repair vias TSV3 may be greater than 175 μm. In some other embodiments, heights of top repair vias TSV3 may be greater than 175 μm. In some embodiments, the bottom logic die 200 may include bottom repair vias (i.e., the conductive members TSV2b) configured in the second region R2 and connecting to the first global repair circuit 204, and a height of one of the bottom repair vias (i.e., the conductive members TSV2b) in a direction where the memory dies D1 to Dm are stacked on each other may be smaller than the height of the one of the top repair vias TSV3. In some other embodiments, heights of the bottom repair vias (i.e., the conductive members TSV2b) in the direction where the memory dies D1 to Dm are stacked on each other may be smaller than the heights of the top repair vias TSV3. In some embodiments, the height of the one of the top repair vias TSV3 may be greater than a height of a via (e.g., one of the conductive members TSV1a or TSV1b) connecting to the device layer 102 or the first local repair circuit 104 in each of the memory dies D1 to Dm in the stacked direction of the memory dies D1 to Dm. In some embodiments, the heights of the top repair vias TSV3 may be greater than heights of vias (e.g., conductive members TSV1a or TSV1b) connecting to the device layer 102 or the first local repair circuit 104 in each of the memory dies D1 to Dm in the stacked direction of the memory dies D1 to Dm.

In some embodiments, a diameter of one of the top repair vias TSV3 may be greater than 20 μm. In some other embodiments, diameters of the top repair vias TSV3 may be greater than 20 μm. In some embodiments, a diameter of one of the bottom repair vias (e.g., one of the conductive members TSV2b) may be smaller than the diameter of the one of the top repair vias TSV3. In some other embodiments, diameters of the bottom repair vias (i.e., the conductive members TSV2b) may be smaller than the diameters of the top repair vias TSV3. In some embodiments, the diameter of the one of the top repair vias TSV3 may be greater than a diameter of a via (e.g., one of the conductive members TSV1a or TSV1b) connecting to the device layer 102 or the first local repair circuit 104 in each of the memory dies D1 to Dm. In some other embodiments, the diameters of the top repair vias TSV3 may be greater than diameters of vias (e.g., conductive members TSV1a or TSVb1) connecting to the device layer 102 or the first local repair circuit 104 in each of the memory dies D1 to Dm.

The redistribution layer RDL1 is disposed on the top die 300 and electrically connected to the top repair vias TSV3. In some embodiments, the redistribution layer RDL1 may include at least one insulation layer and at least one conductive layer alternately stacked along the direction where the memory dies D1 to Dm are stacked on each other. In some embodiments, connection pads CP1 included in the redistribution layer RDL1 and respectively connecting to the top repair via TSV3 can be redistributed, so that the pitch between two adjacent contact pads at the end of the redistribution layer RDL1 contacting test pads TP1 can be greater than the pitch between two adjacent connection pads CP1 at the end of the redistribution layer RDL1 contacting the top repair vias TSV3. Therefore, the test pads TP1 can be formed to have sizes greater than sizes of the connection pads CP1 (e.g., the sizes of the connection pads CP1 are lower than 60 μm). For example, the test pads TP1 may be formed to have a size greater than 100 μm. The insulation layer may include any suitable insulation material. The conductive layer may include any suitable conductive materials such as metals or metal alloys including one or more of Al, AlCu, Cu, Ti, TiN, W, and the like.

The test pads TP1 may be included in the memory device 10 and may be electrically connected to the top repair vias TSV3 through the redistribution layer RDL. The redistribution layer RDL1 may include connection pads CP1 respectively connecting to the top repair vias TSV3 and wirings respectively connecting the test pads TP1 to the connection pads CP1. The test pads TP1, the connection pads CP1, and the wirings may each include any suitable conductive materials such as metals or metal alloys including one or more of Al, AlCu, Cu, Ti, TiN, W, and the like.

In some embodiments, the second global repair circuit 304 in the top die 300 may be configured to receive a control signal from at least one of the test pads TP1. For example, in some embodiments, the second global repair circuit 304 may include a signal Rx buffer circuit (e.g., Buffer 1 shown in FIG. 2), a bidirectional buffer circuit (e.g., Buffer 2 shown in FIG. 2), and electrostatic discharge (ESD) protection circuits (e.g., ESD shown in FIG. 2) connecting to the signal Rx buffer circuit and the bidirectional buffer circuit, respectively. As such, the test control signals from the test pads TP1 and through the top repair vias TSV3 (e.g., Signal 11 or Signal 12 shown in FIG. 2) can transmit to the ESD protection circuit and the signal Rx buffer circuit or the bidirectional buffer circuit before transmit to the control bus of the second global repair circuit 304.

In some embodiments, the top die 300 may be acted as secondary test/repair paths for memory logics and signal paths in the memory dies D1 to Dm. For example, the second global repair circuit 304 in the top die 300 is activated through the test pads TP1, the redistribution layer RDL1, the top repair via TSV3, and the ESD protection circuit (e.g., ESD shown in FIG. 2) and the signal Rx buffer circuit (e.g., Buffer 1 shown in FIG. 2) or the bidirectional buffer circuit (e.g., Buffer 2 shown in FIG. 2) before connecting to the control bus of the second global repair circuit 304. Then, the first local repair circuit 104 in the memory die D1 is activated through the conductive members TSV1b in the memory die D1 from the second global repair circuit 304 in the top die 300. After that, the test and repair action are conducted on the memory die D1. The above steps can be repeated on other memory dies D2 to Dm, so that the test and repair procedures can be activated from the top die 300.

In summary, in the aforementioned memory device, the bottom logic die including the first global repair circuit in the second region and the top die including the second global repair circuit in the second region are respectively at the bottom side and the top side of the memory die stack, and the redistribution layer is disposed on the top die and electrically connected to the second global repair circuit. As such, the test and repair procedures can be activated from the bottom logic die and/or from the top die, and the probing can still be conducted through the redistribution layer after the system assembly, and thus the quality and the yield of the memory device can be improved.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A memory device comprising a first region and a second region, wherein the memory device comprises:
a bottom logic die comprising a first global repair circuit configured in the second region and a first device layer configured in the first region;
a memory die stack on the bottom logic die and comprising at least two memory dies stacked on each other, wherein each memory die comprises a first local repair circuit configured in the second region and a second device layer configured in the first region;
a top die on the memory die stack and comprising a second global repair circuit configured in the second region and a third device layer disposed in the first region, wherein the top die comprises a plurality of top repair vias configured in the second region and connecting to the second global repair circuit; and
a redistribution layer on the top die and electrically connected to the plurality of top repair vias.

2. The memory device according to claim 1, further comprising:
a plurality of test pads on the redistribution layer and electrically connected to the plurality of top repair vias through the redistribution layer.

3. The memory device according to claim 2, wherein the redistribution layer comprises a plurality of connection pads respectively connecting to the plurality of the top repair vias and a plurality of wirings respectively connecting the plurality of test pads to the plurality of connection pads, and sizes of the plurality of connection pads are smaller than sizes of the plurality of test pads.

4. The memory device according to claim 1, wherein the bottom logic die comprises a plurality of bottom repair vias configured in the second region and connecting to the first global repair circuit, and a diameter of one of the plurality of bottom repair vias is smaller than a diameter of one of the plurality of top repair vias.

5. The memory device according to claim 4, wherein the diameter of the one of the plurality of top repair vias is greater than a diameter of a via connecting to the second device layer in each memory die.

6. The memory device according to claim 4, wherein the diameter of the one of the plurality of top repair vias is greater than a diameter of a via connecting to the first local repair circuit in each memory die.

7. The memory device according to claim 4, wherein the diameter of the one of the plurality of top repair vias is greater than 20 μm.

8. The memory device according to claim 1, wherein the bottom logic die comprises a plurality of bottom repair vias configured in the second region and connecting to the first global repair circuit, and a height of one of the plurality of bottom repair vias in a direction where the memory dies are stacked on each other is smaller than a height of one of the plurality of top repair vias.

9. The memory device according to claim 8, wherein the height of the one of the plurality of top repair vias is greater than a height of a via connecting to the second device layer in each memory die in the direction.

10. The memory device according to claim 8, wherein the height of the one of the plurality of top repair vias is greater than a height of a via connecting to the first local repair circuit in each memory die in the direction.

11. The memory device according to claim 8, wherein the height of the one of the plurality of top repair vias is greater than 175 μm.

12. The memory device according to claim 3, wherein the second global repair circuit is configured to receive a control signal from at least one of the plurality of test pads.

13. The memory device according to claim 1, wherein the second global repair circuit comprises a bidirectional buffer circuit.

14. The memory device according to claim 13, wherein the second global repair circuit comprises an electrostatic discharge (ESD) protection circuit connecting to the bidirectional buffer circuit.
